(19) United States
(12) Patent Application Publication
(10) Pub. No.: US 2010/0308440 A1
(43) Pub. Date: Dec. 9, 2010

(54) SEMICONDUCTOR STRUCTURES AND METHODS FOR STABILIZING SILICON-COMPRISING STRUCTURES ON A SILICON OXIDE LAYER OF A SEMICONDUCTOR SUBSTRATE

(75) Inventors: Frank S. JOHNSON, Wappinger Falls, NY (US); Andreas KNORR, Wappinger Falls, NY (US)

Correspondence Address: Ingrassia Fisher & Lorenz, P.C. (GF), 7010 E. Cochise Rd., Scottsdale, AZ, 85253, US

(73) Assignee: GLOBALFOUNDRIES INC., Grand Cayman (KY)

(21) Appl. No.: 12/480,286

(22) Filed: Jun. 8, 2009

(51) Int. Cl. H01L 21/302; H01L 29/06

(52) U.S. Cl. 257/618; 438/694; 257/E21.214; 257/E29.005

(57) ABSTRACT

Methods are provided for substantially preventing and filling overetched regions in a silicon oxide layer of a semiconductor substrate. The overetched regions may be formed as a result of overetching of the silicon oxide layer during etching of an overlying silicon-comprising material layer to form a silicon-comprising structure. An etch resistant spacer may be formed after the initial or subsequent overetches. The etch resistant spacer may be formed by depositing an etch resistant material into the overetched region and etching the deposited etch resistant material to leave residual etch resistant material forming the etch resistant spacer. The etch resistant spacer may also be formed by exposing the silicon oxide layer in the overetched region to a nitrogen-supplying material to form a silicon oxynitride etch resistant spacer.

### FIELD OF THE INVENTION

The present invention generally relates to semiconductor structures and methods for fabricating semiconductor structures, and more particularly relates to stabilized silicon structures and to methods for stabilizing silicon-comprising structures on a silicon oxide layer of a semiconductor substrate, including a FinFET semiconductor structure.

### BACKGROUND OF THE INVENTION

In contrast to traditional planar metal-oxide-semiconductor field-effect transistors (MOSFETs), which are fabricated using conventional lithographic fabrication methods, nonplanar FETs incorporate various vertical transistor structures, and typically include two or more gate electrodes formed in parallel. One such semiconductor structure is the “FinFET,” which takes its name from the multiple thin silicon “fin structures” that are used to form the respective gate channels, and which are typically on the order of tens of nanometers in width.

More particularly, referring to the exemplary prior art nonplanar FET structure shown in FIG. 1, a FinFET generally includes two or more parallel silicon fin structures (or simply “fins”) 12. The fin structures are typically formed on a semiconductor substrate 14 (FIG. 2) with the fin structures extending between a common drain electrode and a common source electrode (not shown). A conductive gate electrode 16 “wraps around” three sides of both fins, and is separated from the fins by a standard gate insulator layer 18. Fins may be suitably doped to produce the desired FET polarity, as is known in the art, such that a gate channel is formed within the near surface of the fins adjacent to gate insulator 18.

FIG. 2 illustrates, in cross-section, the conventional semiconductor substrate 14 comprising a support substrate 20, a silicon oxide layer 22, and a silicon-comprising material layer 24 overlying the silicon oxide layer. The silicon-comprising material layer from which the fin structures are formed and the silicon oxide layer form a silicon on insulator (SOI) structure 26 that, in turn, is supported by the support substrate 20. Fin structures may be formed using any conventional process, including, but not limited to conventional photolithographic and anisotropic etching processes (e.g. reactive ion etching (RIE) or the like). FIGS. 3 and 4 illustrate fin structures formed on the silicon oxide layer from etching the silicon-comprising material layer (not shown in FIGS. 3 and 4).

After the fin structures 12 are formed and cleaned, conventional fabrication processing can be performed to complete the FinFET as illustrated in FIG. 1. A gate insulator is formed overlying the fin structures and a gate electrode forming material such as polycrystalline silicon is deposited over the gate insulator. The gate electrode forming material is patterned to form the at least one gate electrode 16 as is known in the art. The gate electrode is then used as an ion implantation mask and conductivity determining ions are implanted into exposed portions of the fin structures in self alignment with the gate electrode to form source and drain regions (not shown). As those of skill in the art will appreciate, the ion implantation mask may also include sidewall spacers formed on the sides of the gate electrodes and multiple ion implantations may be used to form the source and drain regions.

Unfortunately, as shown in FIG. 3, etching of the silicon-comprising material layer to form the fin structures 12 causes some overetching of the underlying silicon oxide layer 22. Most silicon etchants also etch silicon oxide so any etching of the silicon-comprising material layer will also etch the underlying silicon oxide layer. Oxide will etch faster than silicon to make the silicon oxide layer 22 thinner in the vertical direction and laterally (under the silicon-comprising fin structures). Vertical overetching during fin formation forms silicon oxide pedestals 30 which marginally support the fin structures 12. Horizontal overetching results in undercut regions 28 (or “undercuts”) (not shown in FIG. 3).

Further overetching of the silicon oxide layer 22 during the repeated cleans (particularly Hydrofluoric acid (HF) cleans), etches and other processes involved with formation of the components of FinFET structures after fin formation results in significant undercut regions 28 under the fin structures (See FIG. 4). These undercut regions cause a substantial loss of mechanical support for the fin structures on the silicon oxide layer. If the fin structures are not adequately supported (for example by another structure such as a gate), the inadequately supported fin structures may break off from the silicon oxide layer (herein referred to as a “floating fin structure” 32) causing a missing gate resulting in a defective die.

Accordingly, it is desirable to provide methods for filling previously-formed overetched regions to increase the mechanical support and stabilize the etched silicon-comprising structures on the silicon oxide layer. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Methods are provided for stabilizing an etched silicon-comprising structure on a silicon oxide layer of a semiconductor substrate having a silicon-comprising material layer overlying the silicon oxide layer. In accordance with one exemplary embodiment, a method for stabilizing the etched silicon-comprising structures comprises depositing an etch resistant material into a previously-formed overetched region in the silicon oxide layer. A portion of the deposited etch resistant material is etched to leave residual etch resistant material in the previously-formed overetched region forming an etch resistant spacer. The etch resistant spacer stabilizes the silicon-comprising structure on the silicon oxide layer. The etch resistant material comprises deposited silicon nitride, silicon carbide, or a combination thereof. The deposited etch resistant material may be anisotropically vertically etched.

In accordance with another exemplary embodiment, a method of substantially filling an overetched region in a silicon oxide layer underlying at least one silicon-comprising structure of a semiconductor substrate comprises the steps of providing a semiconductor substrate having a silicon oxide layer and at least one silicon-comprising structure overlying the silicon oxide layer wherein the silicon oxide layer has an overetched region underlying each of the at least one silicon-comprising structure. An etch resistant spacer is formed in the overetched region to fill at least a portion of the overetched region in the silicon oxide layer. The etch resistant spacer may be formed by depositing an etch resistant material in the overetched region and etching a portion of the deposited etch resistant material to leave residual etch resistant material in the overetched region. The etch resistant material comprises deposited silicon nitride, silicon carbide, or a combination thereof. The deposited etch resistant material may be anisotropically vertically etched. The etch resistant spacer may also be formed by exposing the silicon oxide in the overetched region to a nitrogen-comprising material.

### BRIEF DESCRIPTION OF THE DRAWINGS

The present invention will hereinafter be described in conjunction with the following drawing figures, wherein like numerals denote like elements, and wherein:

FIG. 1 is an isometric schematic view of a FinFET structure available in the prior art;

FIG. 2 illustrates, in cross section, a portion of a conventional semiconductor substrate available in the prior art including a silicon substrate, a silicon oxide layer overlying the silicon substrate, and a silicon-comprising material layer overlying the silicon oxide layer;

FIG. 3 illustrates, in cross section, fin structures on the silicon oxide layer of the semiconductor substrate with the fin structures supported on silicon oxide pedestals formed by overetching into the silicon oxide layer during formation of the fin structures;

FIG. 4 illustrates, in cross section, methods for depositing and etching an etch resistant material around the silicon oxide pedestals of FIG. 3 immediately after fin formation to form an etch resistant spacer, in accordance with exemplary embodiments of the present invention; and

FIG. 5 illustrates, in cross section, methods for diffusing nitrogen-comprising material into the silicon oxide layer of the semiconductor substrate to form an etch resistant spacer around the silicon oxide pedestals of FIG. 3, in accordance with exemplary embodiments of the present invention.

FIG. 6 illustrates, in cross section, significant undercut regions beneath the fin structures of FIG. 3 as a result of subsequent lateral overetching into the silicon oxide layer after fin structure formation;

FIG. 7 illustrates, in cross section, methods for depositing and etching an etch resistant material into the significant overetched regions to form an etch resistant spacer therein, in accordance with exemplary embodiments of the present invention;

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

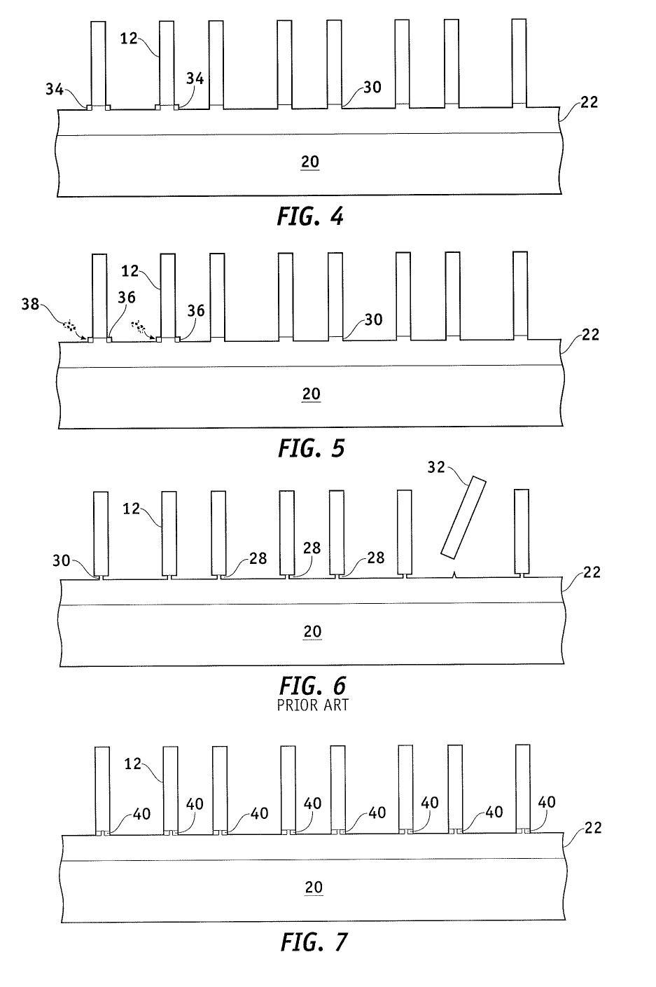

FIGS. 4-5 and 7 illustrate, in cross section, methods in accordance with exemplary embodiments of the present invention for stabilizing silicon-comprising fin structures 12 on a silicon oxide layer 22 of a semiconductor substrate 14 following initial overetching of the silicon oxide layer during fin formation and further overetching of the silicon oxide layer during subsequent cleans and etches. Such overetching includes vertical overetching and lateral overetching. The lateral overetching makes an undercut region under the fin structure. As used herein, “overetched regions” include those formed from vertical overetching and the undercut regions formed from lateral overetching. Such embodiments include the formation of etch resistant spacers 34, 36 or 40 in the previously-formed overetched regions. As used herein, the term “fin structure” and “fin structures” will encompass fin-like vertical orthogonal structures having a high aspect ratio, including those of a FinFET structure. As used herein, the term “overetching” will encompass erosion of the silicon oxide layer 22 of the semiconductor substrate. Such erosion may occur as a result of processes such as cleans, etches and the like involved with the formation of semiconductor structures. In accordance with an embodiment of the invention, stabilization of the fin structures on the silicon oxide layer is performed to substantially prevent the fin structures from breaking off from the silicon oxide layer i.e. to substantially prevent floating fin structures 32.

While the various embodiments particularly refer to the formation of silicon-comprising fin structures, it will be understood that the invention is not so limited. For example, silicon-comprising structures other than fin structures may be formed by etching the silicon-comprising material layer of the semiconductor substrate which may also result in overetching of the underlying silicon oxide layer.

Referring to FIG. 2, in accordance with an exemplary embodiment of the present invention, a method for substantially preventing undercuts in the silicon oxide layer of the semiconductor substrate includes the step of providing the semiconductor substrate 14. The semiconductor substrate 14 has the silicon-comprising material layer 24 overlying the silicon oxide layer 22. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. The semiconductor substrate comprises the bottom silicon oxide (BOX) layer 22 disposed on a support substrate 20. Support substrate 20 is preferably a silicon substrate.

FIG. 3 illustrates, in cross-section, the semiconductor substrate 14 following etching of the silicon-comprising material layer to form the fin structures 12 on the silicon oxide layer 22. Such fin formation results in an initial overetching of the silicon oxide layer 22 forming silicon oxide pedestals 30 which marginally support the fin structures 12. The silicon-oxide pedestals are formed as a result of vertical overetching. Some lateral overetching may also occur during fin formation resulting in an undercut region under the fin structure (no overetched region is shown in FIG. 3)

Referring to FIG. 4, in accordance with an exemplary embodiment of the present invention, as soon as the fin structures are formed and cleaned, the etch resistant spacers 34 around the silicon oxide pedestals 30 may be formed by depositing etch resistant material into the previously-formed overetched regions around the silicon oxide pedestals and then etching a portion of the deposited of the deposited etch resistant material to leave residual etch resistant material around the silicon oxide pedestals. The etch resistant spacers 34 are comprised of etch resistant material selected from the group consisting of silicon nitride, silicon carbide, or a combination thereof. The deposited etch resistant material may be etched using conventional vertical (anisotropic) etching processes, such as reactive ion etching (RIE). The etch resistant spacers 34 protect the underlying silicon oxide and substantially prevent further exposure of the silicon oxide to eroding chemistries. The etch resistant spacers 34 substantially prevent further overetching of the underlying silicon oxide layer during subsequent cleans, etches and other eroding chemistries. The offending chemistry can no longer reach the underlying silicon oxide and cause further erosion thereof. Although the etch resistant spacers 34 are shown around only two of the silicon oxide pedestals in FIG. 4, such etch resistant spacers are intended to represent the etch resistant spacers around all silicon oxide pedestals.

Referring to FIG. 5, in yet another alternative embodiment, etch resistant spacers 36 are formed around the silicon oxide pedestals 30 as soon as the fin structures are formed by diffusing nitrogen-comprising material 38 into the silicon oxide layer in the previously-formed overetched regions around the silicon oxide pedestals. The nitrogen-comprising material reacts with the silicon oxide to form silicon oxynitride. The etch resistant spacers of silicon oxynitride are herein referred to by reference numeral 36. The etch resistant spacers 36 shown in FIG. 5 around only two of the silicon oxide pedestals are intended to represent the etch resistant spacers around all silicon oxide pedestals. The nitrogen-comprising material may be selected from a nitrogen-supplying species. The nitrogen-supplying species may be selected from ammonia, nitrogen gas or another nitrogen-containing molecule or a combination thereof. The etch resistant spacers may be formed using conventional nitridation methods, such as thermal nitridation or plasma nitridation. The thermal nitridation method typically takes place at temperatures of between about 400 degrees to about 1100 degrees Celsius. The plasma nitridation method may use the same nitrogen-comprising materials as stated above using conventional plasma nitriding conditions at lower temperatures to form the etch resistant spacers 36 of silicon oxynitride.

Etch resistant spacers may be formed after initial overetching (i.e. immediately after fin formation) (FIGS. 4-5) or after subsequent cleans and etches during further processing of the semiconductor structure (FIG. 7). As used herein, the term “previously-formed overetched regions” refers to overetched regions formed during fin formation and the significantly undercut regions (See FIG. 6) made during subsequent cleans, etches, and other eroding process steps as hereinafter described.

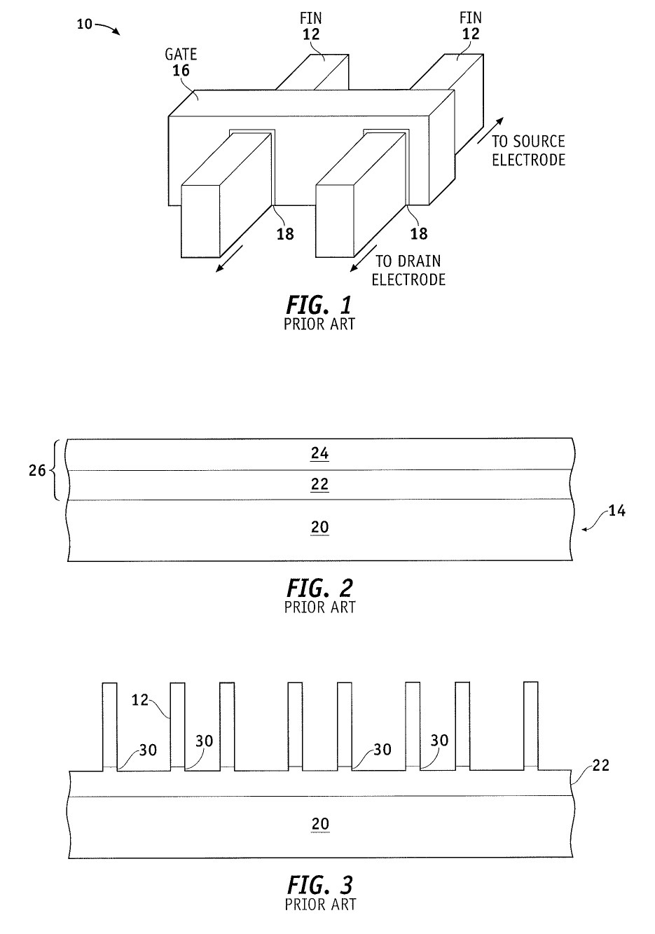

Such further processing is performed to complete the FinFET as illustrated in FIG. 1. A gate insulator 18 is formed overlying the fin structures and a gate electrode 16 forming material such as polycrystalline silicon is deposited over the gate insulator. The gate electrode forming material is patterned to form at least one gate electrode 16 as is known in the art. The gate electrode is then used as an ion implantation mask and conductivity determining ions are implanted into exposed portions of the fin structures 12 in self alignment with the gate electrode to form source and drain regions (not shown). As those of skill in the art will appreciate, the ion implantion mask may also include sidewall spacers (not shown) formed on the sides of the gate electrodes 16 and multiple ion implantations may be used to form the source and drain regions.

FIG. 6 illustrates, in cross section, the semiconductor substrate following such subsequent overetching of the silicon oxide layer as a result of cleaning and etching processes during these steps. The significantly undercut regions 28 in the silicon oxide layer underlying the fin structures further undermine the mechanical stability of the fin structures on the silicon oxide layer.

In yet another exemplary embodiment of the present invention as shown in FIG. 7, etch resistant spacers 40 are formed by depositing an etch resistant material into the previously-formed overetched regions and then etching a portion of the deposited etch resistant material to leave residual etch resistant material in the previously-formed overetched regions. The etch resistant spacers 40 are comprised of etch resistant material selected from the group consisting of silicon nitride, silicon carbide, and a combination thereof. The deposited etch resistant material may be etched using conventional vertical (anisotropic) etching processes, such as reactive ion etching (RIE). The etch-resistant spacers 40 are shown in FIG. 7 as substantially filling the previously-formed undercut regions 28 formed by cleans and etches resulting from and subsequent to fin formation.

Accordingly, methods for substantially stabilizing the silicon-comprising structures on the silicon oxide layer of a semiconductor substrate have been provided. In this regard, the silicon oxide pedestals formed during fin formation may be subsequently covered with an etch resistant material to substantially prevent further overetching and the undercut regions formed during subsequent cleans and etches may be filled to repair the previously-formed undercuts. As a result, the semiconductor structures fabricated with the stabilized silicon-comprising structures exhibit increased mechanical stability thereby reducing die defects.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for stabilizing a silicon-comprising structure on a silicon oxide layer of a semiconductor substrate having an overetched region in the silicon oxide layer, the method comprising the steps of:
depositing an etch resistant material in the overetched region; and
etching a portion of the deposited etch resistant material to leave residual etch resistant material in the overetched region forming an etch resistant spacer, wherein the etch resistant spacer stabilizes the silicon-comprising structure on the silicon oxide layer.

2. The method of claim 1, wherein the step of depositing the etch resistant material comprises depositing the etch resistant material over a silicon oxide pedestal formed in the overetched region when forming a silicon-comprising fin structure.

3. The method of claim 1, wherein the step of depositing the etch resistant material comprises substantially filling at least a portion of the overetched region.

4. The method of claim 1, wherein the step of depositing the etch resistant material comprises depositing silicon nitride, silicon carbide, or a combination thereof.

5. The method of claim 1, wherein the step of etching a portion of the deposited etch resistant material comprises anisotropically etching the deposited etch resistant material.

6. A method of substantially filling an overetched region in a silicon oxide layer underlying at least one silicon-comprising structure of a semiconductor substrate, the method comprising the steps of:
providing a semiconductor substrate having a silicon oxide layer and at least one silicon-comprising structure overlying the silicon oxide layer wherein the silicon oxide layer has an overetched region underlying each of the at least one silicon-comprising structure; and
forming an etch resistant spacer in the overetched region to fill at least a portion of the overetched region in the silicon oxide layer.

7. The method of claim 6, wherein the step of providing a semiconductor substrate comprises providing a semiconductor substrate having the silicon oxide layer and the at least one silicon-comprising structure comprises a fin structure supported by a silicon oxide pedestal in the overetched region.

8. The method of claim 7, wherein the step of forming the etch resistant spacer comprises the steps of:
depositing an etch resistant material over the silicon oxide pedestal; and
etching the deposited etch resistant material to leave residual etch resistant material on the silicon oxide pedestal.

9. The method of claim 8, wherein the step of depositing the etch resistant material comprises depositing silicon nitride, silicon carbide, or a combination thereof.

10. The method of claim 8, wherein the step of etching a portion of the deposited etch resistant material comprises vertically etching the deposited etch resistant material.

11. The method of claim 6, wherein the step of forming the etch resistant spacer in the overetched region comprises the steps of:
depositing an etch resistant material in the overetched region; and
etching the deposited etch resistant material to leave residual etch resistant material in at least a portion of the overetched region.

12. The method of claim 11, wherein the step of depositing the etch resistant material comprises depositing silicon nitride, silicon carbide, or a combination thereof.

13. The method of claim 12, wherein the step of etching a portion of the deposited etch resistant material comprises vertically etching the deposited etch resistant material.

14. The method of claim 7, wherein the step of forming the etch resistant spacer comprises the step of diffusing nitrogen-comprising material into the overetched region around the silicon oxide pedestal.

15. The method of claim 14, wherein the step of diffusing nitrogen-comprising material around the silicon oxide pedestal comprises exposing the silicon oxide pedestal to nitrogen-supplying species.

16. The method of claim 14, wherein the step of diffusing nitrogen-comprising material around the silicon oxide pedestal comprises exposing the silicon oxide pedestal to at least one of ammonia, nitrogen gas or another nitrogen-containing molecule, or a combination thereof, at temperatures of between about 400 degrees to about 1100 degrees Celsius.

17. The method of claim 14, wherein the step of diffusing nitrogen-comprising material into the at least one undercut comprises exposing the silicon oxide pedestal to nitrogen-containing plasma.

18. The method of claim 6, wherein the step of forming the etch resistant spacer comprises forming the etch resistant spacer substantially after completion of a semiconductor structure.

19. The method of claim 6, wherein the step of forming the etch resistant spacer comprises forming the etch resistant spacer immediately after formation of the at least one silicon-comprising structure.

20. A semiconductor structure having at least one stabilized silicon-comprising structure on a silicon oxide layer thereof, comprising:
a semiconductor substrate having a silicon oxide layer;
at least one silicon-comprising structure overlying the silicon oxide layer;
an overetched region in the silicon oxide layer underlying the at least one silicon-comprising structure; and
an etch resistant spacer in the overetched region for providing mechanical support to the at least one silicon-comprising structure.
